(19) United States
(12) Patent Application Publication
(10) Pub. No.: US 2024/0387201 A1
(43) Pub. Date: Nov. 21, 2024

(54) SEMICONDUCTOR MANUFACTURING APPARATUS

(71) Applicant: Mitsubishi Electric Corporation, Tokyo (JP)

(72) Inventors: Hirofumi OKI, Tokyo (JP); Yasuhiro KIMURA, Tokyo (JP); Shigehisa YAMAMOTO, Tokyo (JP); Shinya AKAO, Tokyo (JP)

(73) Assignee: Mitsubishi Electric Corporation, Tokyo (JP)

(21) Appl. No.: 18/619,378

(22) Filed: Mar. 28, 2024

(30) Foreign Application Priority Data
May 19, 2023 (JP) 2023-082686

(51) Int. Cl. H01L 21/67; B24B 7/22; B24B 27/00; H01L 21/683

(52) U.S. Cl. CPC H01L 21/67092; B24B 7/228; B24B 27/0076; H01L 21/6838

(57) ABSTRACT

Provided is a semiconductor manufacturing apparatus that is capable of, while holding one surface of the wafer, grinding the holding surface of a wafer. A semiconductor manufacturing apparatus includes a first main surface holding unit that comes into contact with a center portion of a first main surface of a wafer in plan view and holds the wafer, and a first grinding unit that rotates about a rotation axis that overlaps a center of the wafer in plan view and extends in a direction perpendicular to the first main surface, and that grinds an outer periphery that is a region surrounding the center portion of the first main surface in contact with the outer periphery of the first main surface.

### BACKGROUND OF THE INVENTION

### Field of the Invention

The present disclosure relates to a semiconductor manufacturing apparatus.

### Description of the Background Art

When an epitaxial layer is formed by epitaxial growth on the surface of a wafer, which is a SiC substrate that composes a semiconductor device, a conical protrusion called back surface protrusions may be generated on the back surface of the wafer, particularly at the outer periphery thereof, and also, an annular protrusion called an epicrown along the outer peripheral edge may be generated on the front surface of the wafer, particularly at the outer periphery thereof. The generation of back surface protrusions or epicrowns causes troubles such as defocusing in the photoengraving process of the semiconductor device manufacturing process.

Regarding the protrusions on the wafer, Japanese Patent Application Laid-open No. 58-114849 discloses a grinding device in which, while holding the wafer on the front surface of the wafer, a polishing disk having a cavity in the center is rotated and brought into contact with the outer periphery of the back surface of the wafer, thereby removing the protrusion generated on the outer periphery of the back surface of the wafer.

The device described in Japanese Patent Application Laid-open No. 58-114849 is a device that grinds the back surface of the wafer while holding the front surface of the wafer; therefore, there remains a problem in that no other treatments can be performed such as the removal of a front surface protrusion that generated on the front surface while removal of the back surface protrusion that generated on the back surface of the wafer is in progress.

### SUMMARY

The present disclosure has been made in view of the above-mentioned problems, and an object thereof is to provide a semiconductor manufacturing apparatus that is capable of, while holding one surface of the wafer, grinding the holding surface of a wafer.

According to the present disclosure, a semiconductor manufacturing apparatus includes a first main surface holding unit that comes into contact with a center portion of a first main surface of a wafer in plan view and holds the wafer, and a first grinding unit that rotates about a rotation axis that overlaps a center of the wafer in plan view and extends in a direction perpendicular to the first main surface, and that grinds an outer periphery that is a region surrounding the center portion of the first main surface in contact with the outer periphery of the first main surface.

The simultaneous performance of another processing is enabled on the opposite surface of the first main surface, enabling the implementation of processing on both sides of a wafer in a reduced time.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view illustrating an outline of a semiconductor manufacturing apparatus according to Embodiment 1;

FIG. 2 is a cross-sectional view illustrating an outline of the semiconductor manufacturing apparatus according to Embodiment 1;

FIG. 3 is a schematic cross-sectional view illustrating a semiconductor manufacturing processing according to Embodiment 1;

FIG. 4 is a schematic cross-sectional view illustrating a semiconductor manufacturing processing according to Embodiment 1;

FIG. 5 is a schematic cross-sectional view illustrating a semiconductor manufacturing processing according to Embodiment 1;

FIG. 6 is a schematic cross-sectional view illustrating a semiconductor manufacturing processing according to Embodiment 1;

FIG. 7 is a schematic cross-sectional view illustrating a semiconductor manufacturing processing according to Embodiment 1;

FIG. 8 is a cross-sectional view illustrating an outline of a semiconductor manufacturing apparatus according to Embodiment 2; and

FIG. 9 is a cross-sectional view illustrating an outline of a semiconductor manufacturing apparatus according to Embodiment 3.

### DESCRIPTION OF THE PREFERRED EMBODIMENTS

In the present disclosure, a first main surface of the wafer may be referred to as the wafer back surface, and a second main surface, which is the surface opposite to the first main surface, may be referred to as the wafer front surface. Also, the upward direction in the vertical direction may be referred to as up (upward direction), and as down (downward direction) for the opposite direction of the upward direction. Further, the vertical direction is a direction perpendicular to the first main surface and the second main surfaces of the wafer when the wafer is placed on the apparatus, and the lateral direction is a direction perpendicular to the vertical direction. Further, the planar view refers to the view that is viewed from a direction perpendicular to the first main surface and the second main surface of the wafer when placed on the apparatus, and the cross-sectional view refers to the view that is viewed from a direction parallel to the first main surface and the second main surface of the wafer.

### Embodiment 1

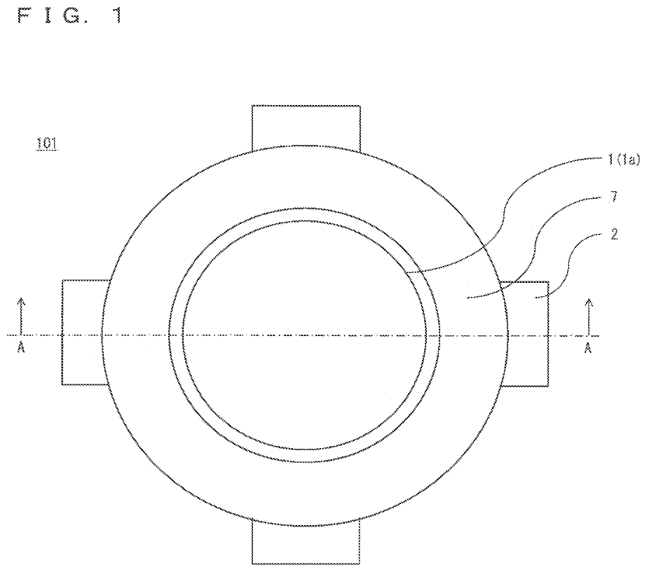

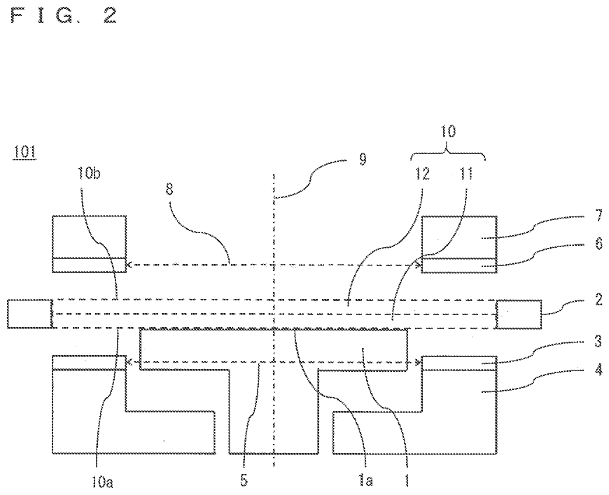

The outline of a semiconductor manufacturing apparatus 101 according to Embodiment 1 will be described. FIG. 1 is a plan view illustrating the outline of the semiconductor manufacturing apparatus 101 viewed from above, and FIG. 2 is a cross-sectional view taken along the line A-A of the semiconductor manufacturing apparatus 101 in FIG. 1. Note that although FIGS. 1 and 2 illustrate the semiconductor manufacturing apparatus 101 and only illustrate the main components for the structure, operation, and effects of the present disclosure, a device housing that is arbitrarily configured, a drive unit (including a motor and a cylinder), and the like, are not illustrated. Also, for better understanding of the description of each component, FIG. 2 illustrates the semiconductor manufacturing apparatus 101 in a state where a wafer 10 indicated by a dotted line is placed on and held in the apparatus.

As illustrated in FIGS. 1 and 2, the semiconductor manufacturing apparatus 101 includes a back surface holding unit 1, which is a first main surface holding unit, that holds the wafer 10 in contact with a wafer back surface 10a, which is the first main surface of the wafer 10, an end surface holding unit 2 that holds the wafer 10 in contact with a wafer end surface, which is the end surface of the outer peripheral edge of the wafer 10, a first grinding unit 3, which is arranged facing the wafer back surface 10a, that grinds in contact with the outer periphery of the wafer back surface 10a, and a second grinding unit 6, which is arranged facing a wafer front surface 10b being the second main surface of the wafer 10 and being the opposite surface to the wafer back surface 10a, that grinds wafer front surface 10b in contact with the wafer front surface 10b. Note that the wafer 10 includes a Si layer 11 on the wafer back surface 10a and an epitaxial layer 12 on the wafer front surface 10b. Each configuration will be described in detail below.

The back surface holding unit 1 is provided inside an apparatus housing (not illustrated), and is a holding means that holds the wafer 10 in contact with the center portion of the wafer back surface 10a. A holding surface 1a being a surface that comes into contact with the wafer 10 on the back surface holding unit 1 has a flat surface, and is further provided with a suction port (not illustrated) connected to a separately provided vacuum pump (not illustrated). By operating the vacuum pump when the holding surface 1a comes into contact with the wafer back surface 10a, the wafer 10 can be vacuum-suctioned adsorbed and held by the holding surface 1a. Note that the back surface holding unit 1 is not limited to such a vacuum-suction type, and any type that allows the wafer 10 to be held may be adoptable.

The end surface holding units 2 are a holding means that holds the wafer 10 in contact with the wafer end surface. The end surface holding units 2, which are attached to the apparatus housing (not illustrated), hold the wafer 10 by pressing an air cylinder (not illustrated) to which an end surface holding plate having the same thickness as the wafer 10 is connected against the wafer end surface toward the center of the wafer 10. While FIG. 2 illustrates a state in which the end surface holding units 2 hold the wafer 10, each end surface holding unit 2 retracts outward from the wafer 10 when releasing the holding. The end surface holding units 2 do not need to be in contact with the entire circumference of the wafer end surface, and need only be provided at a plurality of positions so as to face each other with the wafer 10 in between. In Embodiment 1, as illustrated in FIG. 1, the end surface holding units 2 are provided at four locations outside the outer peripheral edge of the wafer 10. The end surface holding units 2 suppresses the outer periphery of the wafer 10 from moving up and down in the front and back directions and from shifting the wafer 10 in the lateral direction during grinding.

The end surface holding units 2 are not limited to a structure of the air cylinder pressing the end surface holding plate, and a structure of pressing an end surface holding plate having elasticity may be adopted. The end surface holding units 2 can have a plurality of end surface holding plates. The holding of the wafer 10 may be sufficient as long as the wafer 10 is held without coming off or shifting during grinding, and if either the back surface holding unit 1 or the end surface holding units 2 has sufficient holding force, the other may be eliminated.

The first grinding unit 3 is arranged facing the wafer back surface 10a, and grinds the outer periphery of the wafer back surface 10a, and is made of an abrasive material, such as a grindstone containing diamond abrasive grains. The first grinding unit 3 has an annular shape in plan view, and has a first cutout portion 5, which is a cutout region, in the center portion. The back surface holding unit 1 is arranged so as to overlap the first cutout portion 5 in plan view, and comes into contact with the center portion of the wafer back surface 10a to hold the wafer 10. The first grinding unit 3 is attached to a first grinding stage 4.

The first grinding stage 4 is connected to a first motor (not illustrated) that rotates the first grinding stage 4. As the first motor rotates, the first grinding stage 4 and the first grinding unit 3 attached thereto are rotated about a rotation axis 9 perpendicular to the holding surface 1a of the back surface holding unit 1, that is, perpendicular to the wafer back surface 10a. The first motor is connected to a control unit (not illustrated) that can arbitrarily set the rotation direction and rotational speed.

Further, the first grinding stage 4 is connected to a first vertical drive unit (not illustrated) that moves the position of the first grinding stage 4 up and down in a direction perpendicular to the holding surface 1a. When the first vertical drive unit is driven, the first grinding unit 3 moves up and down together with the first grinding stage 4, and whether or not it comes into contact with the wafer back surface 10a is controlled. The semiconductor manufacturing apparatus 101 further includes a first sensor (not illustrated) that detects the position of the first grinding stage 4 in a direction perpendicular to the holding surface 1a. The first vertical drive unit and the first sensor are connected to the control unit, and the control unit can control the first vertical drive unit and vertically change the position of the first grinding stage 4 based on position information from the first sensor.

The second grinding unit 6 is arranged facing the wafer front surface 10b and grinds the outer periphery of the wafer front surface 10b. The semiconductor manufacturing apparatus 101, in which the second grinding unit 6 is attached to the second grinding stage 7, the further includes a second motor (not illustrated) that rotates the second grinding stage 7 around the rotation axis 9, a second vertical drive unit (not illustrated) that changes the position of the second grinding stage 7 in the direction perpendicular to the holding surface 1a, and a second sensor (not illustrated) that detects the position of the second grinding stage 7 in the direction perpendicular to the holding surface 1a. The configurations and functions of the second motor, the second vertical drive unit, and the second sensor are the same as those of the first motor, the first vertical drive unit, and the first sensor, and descriptions thereof will be omitted.

In the first grinding unit 3, the first cutout portion 5 is provided in the center portion, and a second cutout portion 8 being a cutout region cut out the center portions of the second grinding unit 6 and the second grinding stage 7 is provided also in the second grinding unit 6. However, in the second grinding unit 6, instead of the second cutout portion 8, a recess portion may be provided in the region of the second cutout portion 8, which is recessed in a direction away from the second main surface. With the second cutout portion 8 or the recess portion provided, the second grinding unit 6 comes into contact with only the outer periphery of the wafer front surface 10b, thereby enabling to grind only the outer periphery of the wafer front surface 10b.

In addition, when grinding the wafer 10 using a wet method, a water supply unit (not illustrated) that supplies liquid such as water between the wafer back surface 10a and the first grinding unit 3 and between the wafer front surface 10b and the second grinding unit 6 during the grinding may also be provided.

Next, the operation of the semiconductor manufacturing apparatus 101 in the semiconductor manufacturing processing will be explained. The following description is on a wafer manufacturing processing in the semiconductor manufacturing process, and more specifically, is on the operation of the semiconductor manufacturing apparatus 101 in the wafer grinding process after the epitaxial growth process. Note that the drawings illustrated in the description are cross-sectional views schematically illustrating the wafer grinding process. While regarding the semiconductor manufacturing apparatus 101, the same cross section as the A-A cross section in FIG. 1 is illustrated, only the main components of the structure, operation, and effects of the present disclosure are illustrated, the arbitrarily configured device housing, drive unit (including motor and cylinder), etc. are not illustrated.

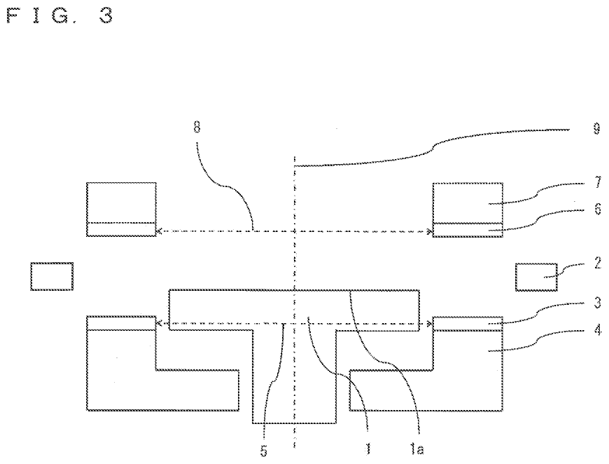

In the wafer grinding process after the epitaxial growth process, a loading process of loading the wafer 10 into the semiconductor manufacturing apparatus 101 is first performed. FIG. 3 is a cross-sectional view schematically illustrating the loading process before loading the wafer. As illustrated in FIG. 3, before the wafer 10 is loaded in, the first grinding unit 3 and the second grinding unit 6 are retracted to positions where they are spaced apart from each other in the vertical direction of the sheet, and the end surface holding units 2 are also retracted outward in the left and right direction of the sheet.

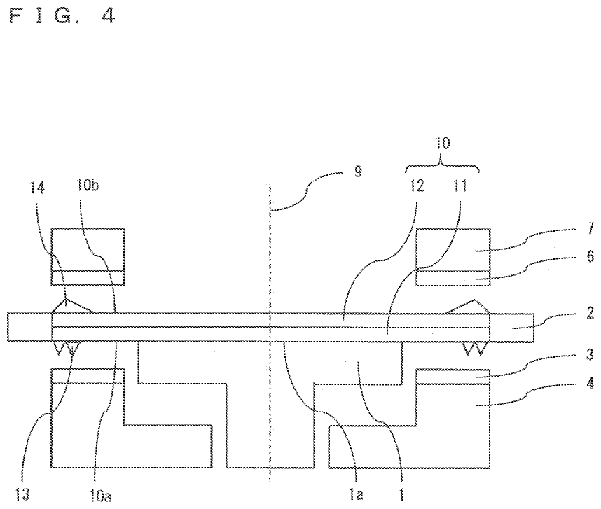

Next, in this state, the wafer 10 is placed on the back surface holding unit 1 by a transfer hand (not illustrated), and is held by the back surface holding unit 1 and the end surface holding unit 2. FIG. 4 is a cross-sectional view schematically illustrating the loading process after loading the wafer. As illustrated in FIG. 4, when the wafer 10 is loaded onto the holding surface 1a of the back surface holding unit 1, a vacuum pump of the back surface holding unit 1 is turned on, and the wafer 10 is adsorbed to the holding surface 1a of the back surface holding unit 1. Next, the end surface holding units 2 move toward the center of the wafer 10, holding the wafer 10 from the lateral direction in contact with the wafer end surface. At this point, the wafer 10 is held at a position where the center of the wafer 10 and the rotation axis 9 overlap in plan view.

Note that the transfer hand may be provided in the semiconductor manufacturing apparatus 101, or may also be provided in another device such as a transfer robot, for example.

In the loading process, the wafer 10 is loaded so that the wafer back surface 10a faces the first grinding unit 3 and the wafer front surface 10b faces the second grinding unit 6. Here, the wafer back surface 10a is the surface that was the back surface during the epitaxial process and that is the surface of the wafer 10 on which side the Si layer 11 is provided. Also, the wafer front surface 10b is the surface that was the front surface during the epitaxial process and that is the surface of the wafer 10 on which side the epitaxial layer 12 is provided. Although further details will be described later, protrusions 13 generated on the outer periphery of the wafer back surface 10a, and a protrusion 14 generated on the outer periphery of the wafer front surface 10b.

When the wafer 10 is loaded in the loading process, the grinding process is then performed to grind the protrusions 13 on the wafer back surface 10a and the protrusion 14 on the wafer front surface 10b. In the grinding process, first the first motor and the second motor are started, and the first grinding stage 4 and the second grinding stage 7 rotate in the reversed rotation directions to each other about the rotation axis 9. While the rotation directions may be the same, adopting the manner of reversed rotation direction prevents the wafer 10 from shifting and rotating in the rotation direction of the upper and lower grinding stages.

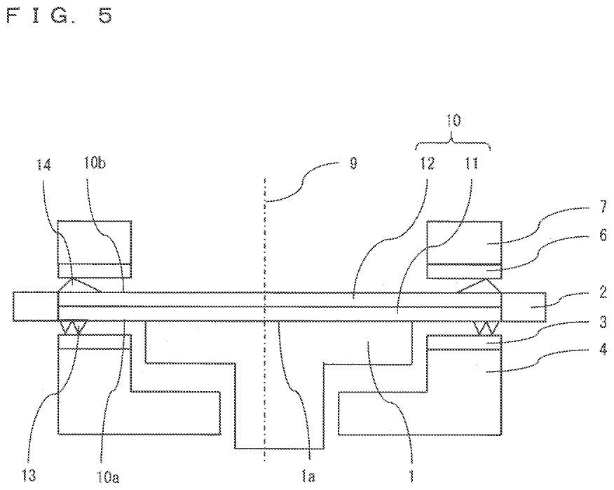

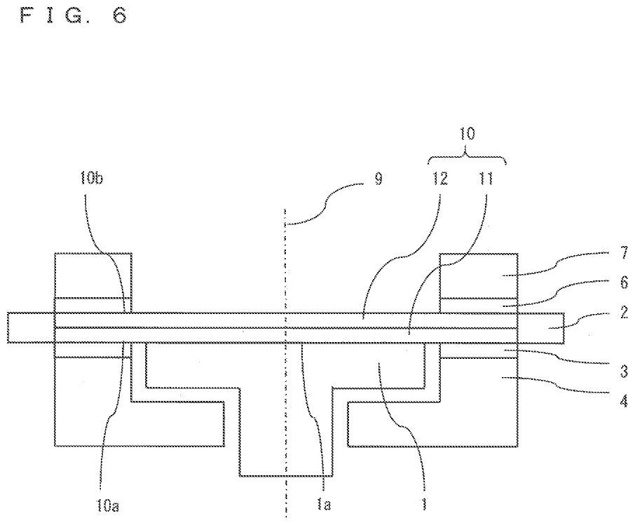

Next, the first vertical drive unit and the second vertical drive unit are driven, and the first grinding unit 3 and the second grinding unit 6 are brought close to and in contact with the wafer back surface 10a and the wafer front surface 10b, respectively, and grinding is performed. FIGS. 5 and 6 are cross-sectional views schematically illustrating the wafer grinding process. As the first grinding stage 4 and the second grinding stage 7 approach the wafer back surface 10a and the wafer front surface 10b, respectively, as illustrated in FIG. 5, first, the first grinding unit 3 and the protrusions 13 on the wafer back surface 10a come into contact with each other, the second grinding unit 6 and the protrusion 14 on the wafer front surface 10b come into contact with each other, and the protrusions 13 and the protrusion 14 are ground.

Then, when the first grinding stage 4 and the second grinding stage 7 further approach the wafer 10, the protrusions 13 and the protrusion 14 are ground and removed, as illustrated in FIG. 6, the distance between the first grinding unit 3 and the second grinding unit 6 in the vertical direction becomes equal to the thickness of the wafer in the region where no protrusions are present. At this point, the protrusion 13 and the protrusion 14 are removed, and the determination that the grinding is complete is made in the control unit. For the distance between the first grinding unit 3 and the second grinding unit 6, position information of the first sensor and the second sensor that detect the positions of the first grinding stage 4 and the second grinding stage 7 is used.

When the control unit determines that the grinding is completed, the first vertical drive unit and the second vertical drive unit retract the first grinding stage 4 and the second grinding stage 7, respectively, that were in contact with the wafer 10. Then, the first motor and the second motor stop, and the rotation of the first grinding stage 4 and the second grinding stage 7 stop.

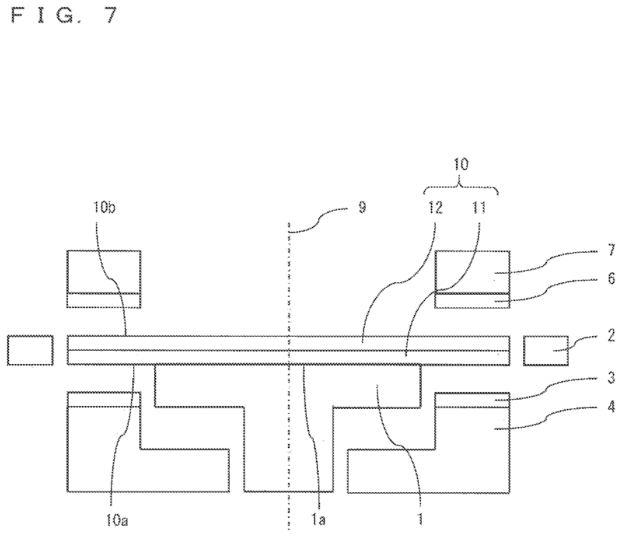

When the grinding process ends, the wafer 10 is unloaded in an unloading process. FIG. 7 is a cross-sectional view schematically illustrating the unloading process. In the unloading process, as illustrated in FIG. 7, the first grinding stage 4 and the second grinding stage 7 are retracted so that the first grinding unit 3 and the second grinding unit 6 move away from the wafer 10, and further, the end surface holding units 2 are retracted outwardly from the wafer 10, thereby releasing the holding of the end surface of the wafer 10. Then, the transfer hand moves over the wafer 10 and holds the wafer 10, the vacuum suction of the back surface holding unit 1 is released, and the transfer hand carries the wafer 10 out of the apparatus.

The effect of the semiconductor manufacturing apparatus 101 of Embodiment 1 will be described. To explain the effects, first, the protrusion 13 and the protrusion 14 that are generated on the wafer back surface 10a and the wafer front surface 10b during epitaxial growth will be explained. Epitaxial growth is one of the thin film crystal growth techniques used in semiconductor device manufacturing, and is a process technology for growing a new single crystal thin film on a semiconductor single crystal substrate. One method of epitaxial growth is, for example, Vapor Phase Epitaxy (VPE) or Chemical Vapor Deposition (CVD) in which components in a gas phase are deposited on a substrate crystal surface.

For example, in a case where epitaxial growth is performed when wafer 10 is a SiC substrate composed of SiC, on the wafer back surface 10a, a back surface protrusion (corresponding to the protrusion 13), which is barnacle-shaped protrusions with a height of about 5 to 6 μm, may be generated on the outer periphery, especially around the orientation flat part, or on the wafer front surface 10b, an epicrown (corresponding to the protrusion 14), which is an annular protrusion with a height of about 15 to 20 μm, may be generated at the outer periphery. These back surface protrusions and epicrown impair the flatness of the wafer 10, and may cause problems such as defocusing in the photoengraving process of the semiconductor manufacturing processing.

Therefore, in the wafer manufacturing process, a step of grinding the front surface of the wafer 10 by a wafer grinding device is provided in some cases in order to remove these back surface protrusions and epicrown. However, conventional wafer grinding device holds one side of the wafer 10 and grinds the opposite side, it was necessary to first polish one side, then turn the wafer 10 over and grind the other side to remove the back surface protrusions on the wafer back surface 10a and the epicrown on the wafer front surface 10b. Whereas, in the semiconductor manufacturing apparatus 101 according to Embodiment 1, the first grinding unit 3 grinds the outer periphery of the wafer back surface 10a while the back surface holding unit is in contact with the center portion of the wafer back surface 10a and holds the wafer 10, thereby enabling simultaneous performance of another process on the wafer front surface 10b. Therefore, providing the second grinding unit 6 that grinds the wafer front surface 10b allows simultaneous performance of the grinding process on the outer periphery of the wafer front surface 10b, this enables reduction in about time taking to grind one side of the wafer 10 and time taking to invert and reload the wafer 10 more than conventional grinding devices, resulting in an effect of improving throughput.

### Embodiment 2

In Embodiment 1, the semiconductor manufacturing apparatus 101 has been described which is capable of simultaneously grinding back surface protrusions generated on the outer periphery of the wafer back surface 10a and the epicrown generated on the outer periphery of the wafer front surface 10b on both sides. In Embodiment 2, a semiconductor manufacturing apparatus 102 that is capable of more easily grinding an epicrown generated on the wafer front surface 10b will be described. Note that the description of the same configurations as in Embodiments 1 is omitted.

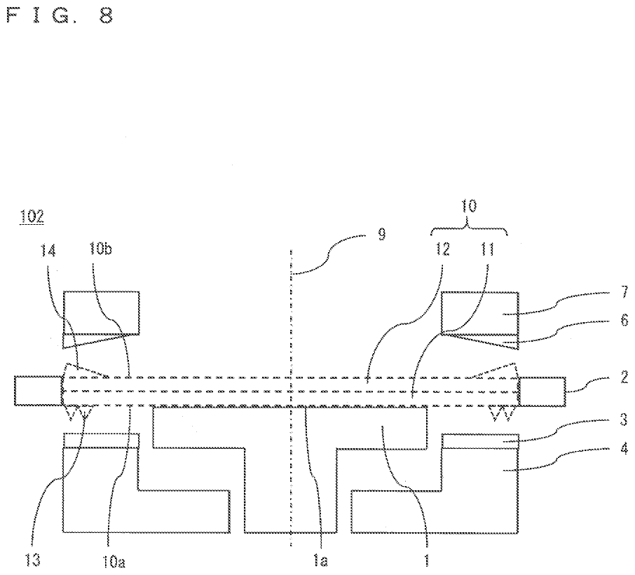

FIG. 8 is a cross-sectional view illustrating a cross section of the semiconductor manufacturing apparatus 102, and illustrates a cross section at a position corresponding to the A-A cross section of the semiconductor manufacturing apparatus 101 in Embodiment 1. Note that although FIG. 8 illustrates the semiconductor manufacturing apparatus 102 and only illustrate the main components for the structure, operation, and effects of the present disclosure, a device housing that is arbitrarily configured, a drive unit (including a motor and a cylinder), and the like, are not illustrated. Also, for better understanding of the description of each component, FIG. 8 illustrates the semiconductor manufacturing apparatus 102 in a state where a wafer 10 indicated by a dotted line is placed on and held in the apparatus.

The semiconductor manufacturing apparatus 102 differs from the semiconductor manufacturing apparatus 101 in the shape of the second grinding unit 6 that grinds the wafer front surface 10b. That is, while the surface of the second grinding unit 6 of the semiconductor manufacturing apparatus 101 that comes into contact with the wafer front surface 10b is parallel to the wafer front surface 10b, as illustrated in FIG. 8, the second grinding unit 6 of the semiconductor manufacturing apparatus 102 has a surface that comes into contact with the wafer front surface 10b, which is sloped and not parallel to the wafer front surface 10b, which, more specifically, has a shape such that the distance between the second grinding unit 6 and the wafer front surface 10b decreases as the distance from the rotation axis 9 increases. That is, the second grinding unit 6 has a region which is closer to the second main surface in the direction in which the rotation axis 9 extends as a distance from the rotation axis 9 increases in plan view.

The effect of Embodiment 2 will be described. As illustrated in FIG. 8, the epicrown that generates on the outer periphery of the wafer front surface 10b has a protrusion that is prone to gradually increase in height in the direction from the center of the wafer 10 toward the outer periphery, except for the region extremely close to the outer periphery of the wafer 10. Therefore, in order to remove the epicrown by grinding, the closer to the outer peripheral edge of the wafer 10, the more grinding is required. In the semiconductor manufacturing apparatus 102 according to Embodiment 2, the surface of the second grinding unit 6 that comes into contact with the wafer front surface 10b has a slope that is closer to the wafer front surface 10b from the rotation axis 9 toward the outer periphery; therefore, the closer to the outer peripheral edge of the wafer 10, the faster the second grinding unit 6 can contact the wafer front surface 10b with more powerful pressure to perform grinding. Consequently, the effect of the epicrown on the wafer front surface 10b being able to be removed more efficiently and in a shorter time is exhibited.

### Embodiment 3

In Embodiment 1, the semiconductor manufacturing apparatus 101 has been described which is capable of simultaneously grinding back surface protrusions generated on the outer periphery of the wafer back surface 10a and the epicrown generated on the outer periphery of the wafer front surface 10b on both sides. Embodiment 3 will describe a semiconductor manufacturing apparatus 103 that is capable of simultaneous grinding of epitaxial defects generated on the wafer front surface 10b in addition to back surface protrusions and an epicrown. Note that the description of the same configurations as in Embodiments 1 is omitted.

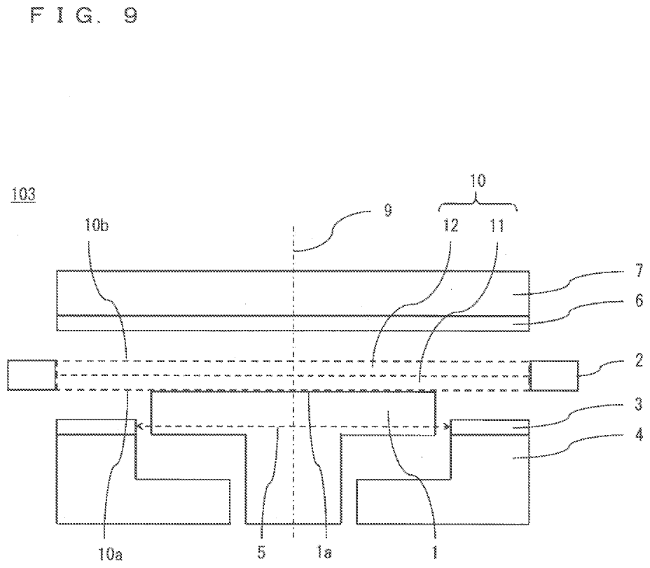

FIG. 9 is a cross-sectional view illustrating a cross section of the semiconductor manufacturing apparatus 103, and illustrates a cross section at a position corresponding to the A-A cross section of the semiconductor manufacturing apparatus 101 in Embodiment 1. Note that although FIG. 9 illustrates the semiconductor manufacturing apparatus 103 and only illustrate the main components for the structure, operation, and effects of the present disclosure, a device housing that is arbitrarily configured, a drive unit (including a motor and a cylinder), and the like, are not illustrated. Also, for better understanding of the description of each component, FIG. 9 illustrates the semiconductor manufacturing apparatus 103 in a state where a wafer 10 indicated by a dotted line is placed on and held in the apparatus.

The semiconductor manufacturing apparatus 103 differs from the semiconductor manufacturing apparatus 101 in the shapes of the second grinding unit 6 that grinds the wafer front surface 10b and the second grinding stage 7. That is, while the second grinding unit 6 and the second grinding stage 7 of the semiconductor manufacturing apparatus 101 have the second cutout portion 8 in the center portions, the second grinding unit 6 and the second grinding stage 7 of the semiconductor manufacturing apparatus 103 do not have a cutout portion in the center portions, and the second grinding unit 6 is configured to come into contact with the entire surface of the wafer front surface 10b.

In addition to the above-mentioned epicrown, defects such as protrusions and depressions may be generated on the wafer front surface 10b through epitaxial growth. These are collectively called epi defects. Unlike an epicrown which mainly is generated on the outer periphery of the wafer front surface 10b, epi defects may be generated over the entire surface including the center portion. In the semiconductor manufacturing apparatus 103, the second grinding unit 6 for grinding the wafer front surface 10b is provided in a region corresponding to the entire surface of the wafer front surface 10b without a cutout portion, this exhibits the effect that epitaxial defects appeared in the center portion of the wafer front surface 10b are also ground when the second grinding unit 6 rotates.

Note that, although in Embodiments 1 to 3, the surface of the first grinding unit 3 that comes into contact with the wafer back surface 10a is parallel to the wafer 10, the surface is not limited thereto, and as in the second grinding unit 6 in Embodiment 2, the surface that comes into contact with the wafer 10 may have a shape that is sloped with respect to the wafer 10. In the case where the number of protrusions 13 or the height of the protrusions 13 increases on the wafer back surface 10a as the distance from the rotation axis 9 increases, more efficient grinding of the protrusions 13 is implemented by having the form in which, similar to the second grinding unit 6, the distance between the first grinding unit 3 and the wafer back surface 10a becomes smaller as the first grinding unit 3 becomes farther from the rotation axis 9.

In Embodiments 1 to 3, the determination of completion of grinding of protrusions in the grinding process is implemented by detecting that the distance between the first grinding unit 3 and the second grinding unit 6 is equal to the thickness of the wafer 10 without any protrusions using the first sensor that detects the position of the first grinding stage 4 and the second sensor that detects the position of the second grinding stage 7. However, the method is not limited thereto, and for example, an optical sensor may be separately provided to measure the distance between the first grinding unit 3 and a flat portion of the wafer back surface 10a with no protrusions and the distance between the second grinding stage 7 and the flat portion of the wafer front surface 10b with no protrusions and used for the determination. Alternatively, for example, the removal of protrusions may be determined by the control unit monitoring the current value flowing through the first motor and the second motor to detect the change in the load applied to the first grinding unit 3 and the second grinding unit 6 based on the change in the current value during grinding.

In Embodiments 1 to 3, the rotational speed of the first grinding stage 4 and the second grinding stage 7, that is, the rotation rate per unit time can be changed. For example, the epicrown on the wafer front surface 10b may be more unlikely to be removed by grinding than the back surface protrusions generated on the wafer back surface 10a, and take more time for grinding. In such a case, an increase in rotational speed of the second grinding unit 6 higher than the rotational speed of the first grinding unit 3 allows to shorten the time for grinding the wafer front surface 10b, exhibiting throughput improvement.

In Embodiments 1 to 3, the first grinding unit 3 has an annular shape. However, the shape is not limited thereto, and for example, one or more blocks that are not annularly continuous in the rotation direction may be arranged on the first grinding stage 4. Even if the first grinding stage 4 is arranged in such a block shape, it is sufficient that the first grinding stage 4 rotates to come into contact with a desired annular region on the outer periphery of the wafer back surface 10a. Similarly, although the second grinding unit 6 has an annular shape in Embodiments 1 and 2, and a circular shape in Embodiment 3, the second grinding unit 6 may be arranged in one or more blocks that are not annularly continuous in the rotation direction.

In Embodiments 1 to 3, back surface holding unit 1 is arranged below the wafer 10 in the vertical direction. Therefore, the wafer 10 is held so that the wafer front surface 10b faces upward and the wafer back surface 10a faces downward in the vertical direction. However, in a reversed manner, the back surface holding unit 1 may be placed above the wafer 10 in the vertical direction, and the wafer 10 may be held so that the wafer front surface 10b faces downward and the wafer back surface 10a faces upward in the vertical direction. With this configuration, reduction of grinding debris generated during the grinding of the wafer 10 falling down due to gravity and intruding between the first grinding stage 4 and the back surface holding unit 1 is ensured, exhibiting the effect of suppressing malfunctions of the first grinding stage 4 and the back surface holding unit 1.

In Embodiments 1 to 3, the wafer 10 is held by the back surface holding unit 1, and the first grinding unit 3 and the second grinding unit 6 rotate to grind the wafer back surface 10a and the wafer front surface 10b. However, in a reversed manner, the wafer 10 held by the back surface holding unit 1 may rotate together with the back surface holding unit 1, and the first grinding unit 3 and the second grinding unit 6 may be fixed without rotating. Further, even if the wafer 10 rotates together with the back surface holding unit 1 and the first grinding unit 3 and the second grinding unit 6 rotate, this is adoptable as long as the rotation speeds thereof differ. For these, a configuration that facilitates the manufacturing of the device may be adopted, for example.

In Embodiments 1 to 3, the first grinding unit 3 grinds the outer periphery of the wafer back surface 10a while the back surface holding unit is in contact with the center portion of the wafer back surface 10a and holds the wafer 10, thereby enabling simultaneous grounding of the wafer front surface 10b by the arrangement of the second grinding unit 6 on the side facing the wafer front surface 10b. However, the process performed on the wafer front surface 10b is not limited to grinding. For example, a configuration may be adopted in which a cleaning processing mechanism such as an air blower, a cleaning water (cleaning liquid) spray, and the like, which are a cleaning means for the wafer 10, is placed at a position facing the wafer front surface 10b, and the cleaning process for the wafer front surface 10b is performed simultaneously as the wafer back surface 10a is being ground.

While Embodiments of the present disclosure have been described, the foregoing Embodiments are in all aspects illustrative. Various omissions, substitutions, and changes can be made without departing from the scope of Embodiments. It should be noted that each Embodiment can be combined with other Embodiment. Further, the scope of the present disclosure is indicated by the claims rather than the above description, and it is intended that all changes within the meaning and scope equivalent to the claims are included.

Hereinafter, the aspects of the present disclosure will be collectively described as Appendices.

### Appendix 1

A semiconductor manufacturing apparatus comprising:
a first main surface holding unit that comes into contact with a center portion of a first main surface of a wafer in plan view and holds the wafer; and
a first grinding unit that rotates about a rotation axis that overlaps a center of the wafer in plan view and extends in a direction perpendicular to the first main surface, and that grinds an outer periphery that is a region surrounding the center portion of the first main surface in contact with the outer periphery of the first main surface.

### Appendix 2

The semiconductor manufacturing apparatus according to Appendix 1, wherein the first grinding unit has a first cutout portion which is a cutout region in a center in plan view, and the first main surface holding unit is arranged to overlap with the first cutout portion in plan view.

### Appendix 3

The semiconductor manufacturing apparatus according to Appendix 1 or 2, further comprising
a second grinding unit that rotates around the rotation axis and grinds a second main surface that is the opposite surface of the first main surface in contact with the second main surface.

### Appendix 4

The semiconductor manufacturing apparatus according to Appendix 3, wherein
the second grinding unit has a second cutout portion, which is a cutout region, or a recess portion that is a region recessed in a direction away from the second main surface, in a center in plan view.

### Appendix 5

The semiconductor manufacturing apparatus according to Appendix 3 or 4, wherein
the second grinding unit has a region which is closer to the second main surface in a direction in which the rotation axis extends as a distance from the rotation axis increases in plan view.

### Appendix 6

The semiconductor manufacturing apparatus according to Appendix 3, wherein
the second grinding unit comes into contact with an entire surface of the second main surface.

### Appendix 7

The semiconductor manufacturing apparatus according to any one of Appendices 3 to 6, wherein
a rotation direction of the second grinding unit is a reversed direction of a rotation direction of the first grinding unit.

### Appendix 8

The semiconductor manufacturing apparatus according to any one of Appendices 3 to 7, wherein
a rotation rate per unit time of the second grinding unit is greater than a rotation rate per unit time of the first grinding unit.

### Appendix 9

The semiconductor manufacturing apparatus according to any one of Appendices 1 to 8, wherein
the first main surface holding unit adsorbs the first main surface by vacuum suction to hold the wafer.

### Appendix 10

The semiconductor manufacturing apparatus according to any one of Appendices 1 to 9, wherein
the first main surface holding unit holds the wafer so that the first main surface faces downward in vertical direction with respect to a second surface which is a surface opposite to the first main surface.

### Appendix 11

The semiconductor manufacturing apparatus according to Appendices 1 to 10, further comprising
an end face holding unit that holds the wafer in contact with an end surface of the wafer.

While the invention has been illustrated and described in detail, the foregoing description is in all aspects illustrative and not restrictive. It is therefore understood that numerous modifications and variations can be devised without departing from the scope of the invention.

What is claimed is:

1. A semiconductor manufacturing apparatus comprising:
a first main surface holding unit that comes into contact with a center portion of a first main surface of a wafer in plan view and holds the wafer; and
a first grinding unit that rotates about a rotation axis that overlaps a center of the wafer in plan view and extends in a direction perpendicular to the first main surface, and that grinds an outer periphery that is a region surrounding the center portion of the first main surface in contact with the outer periphery of the first main surface.

2. The semiconductor manufacturing apparatus according to claim 1, wherein
the first grinding unit has a first cutout portion which is a cutout region in a center in plan view, and the first main surface holding unit is arranged to overlap with the first cutout portion in plan view.

3. The semiconductor manufacturing apparatus according to claim 1, further comprising
a second grinding unit that rotates around the rotation axis and grinds a second main surface that is the opposite surface of the first main surface in contact with the second main surface.

4. The semiconductor manufacturing apparatus according to claim 3, wherein
the second grinding unit has a second cutout portion, which is a cutout region, or a recess portion that is a region recessed in a direction away from the second main surface, in a center in plan view.

5. The semiconductor manufacturing apparatus according to claim 3, wherein
the second grinding unit has a region which is closer to the second main surface in a direction in which the rotation axis extends as a distance from the rotation axis increases in plan view.

6. The semiconductor manufacturing apparatus according to claim 3, wherein
the second grinding unit comes into contact with an entire surface of the second main surface.

7. The semiconductor manufacturing apparatus according to claim 3, wherein
a rotation direction of the second grinding unit is a reversed direction of a rotation direction of the first grinding unit.

8. The semiconductor manufacturing apparatus according to claim 3, wherein
a rotation rate per unit time of the second grinding unit is greater than a rotation rate per unit time of the first grinding unit.

9. The semiconductor manufacturing apparatus according to claim 1, wherein
the first main surface holding unit adsorbs the first main surface by vacuum suction to hold the wafer.

10. The semiconductor manufacturing apparatus according to claim 1, wherein
the first main surface holding unit holds the wafer so that the first main surface faces downward in vertical direction with respect to a second surface which is a surface opposite to the first main surface.

11. The semiconductor manufacturing apparatus according to claim 1, further comprising
an end face holding unit that holds the wafer in contact with an end surface of the wafer.
